(19) United States
(12) Patent Application Publication
(10) Pub. No.: US 2012/0211801 A1
(43) Pub. Date: Aug. 23, 2012

(54) GROUP III NITRIDE LAMINATED SEMICONDUCTOR WAFER AND GROUP III NITRIDE SEMICONDUCTOR DEVICE

(75) Inventors: Shin Hashimoto, Itami-shi (JP); Katsushi Akita, Itami-shi (JP); Hideaki Nakahata, Itami-shi (JP); Hiroshi Amano, Nagoya-shi (JP)

(73) Assignee: SUMITOMO ELECTRIC INDUSTRIES, LTD., Osaka-shi (JP)

(21) Appl. No.: 13/392,998

(22) PCT Filed: Aug. 23, 2010
(86) PCT No.: PCT/JP10/64174

§ 371 Date: May 8, 2012

(30) Foreign Application Priority Data
Aug. 28, 2009 (JP) 2009-198746

(51) Int. Cl. H01L 29/778; H01L 29/205

(52) U.S. Cl. 257/194; 257/201; 257/E29.091; 257/E29.245

(57) ABSTRACT

There is provided a normally-off group III nitride semiconductor device having a high breakdown field strength and minimal crystal defects, and a group III nitride laminated semiconductor wafer used to make the group III nitride semiconductor device. The group III nitride laminated semiconductor wafer 10 includes a substrate 27 which is made of AlN and has a main surface 27a along the c-axis of the AlN crystal, a first Al_{X1}In_{Y1}Ga_{1-X1-Y1}N layer 13 which is made of a group III nitride-based semiconductor containing Al and is provided on the main surface 27a, and a second Al_{X2}In_{Y2}Ga_{1-X2-Y2}N layer 15 which is provided on the main surface 27a, is made of a group III nitride-based semiconductor having a larger bandgap than the first Al_{X1}In_{Y1}Ga_{1-X1-Y1}N layer 13, and forms a heterojunction with the first Al_{X1}In_{Y1}Ga_{1-X1-Y1}N layer 13.

### TECHNICAL FIELD

The present invention relates to a group III nitride laminated semiconductor wafer and a group III nitride semiconductor device.

### BACKGROUND ART

Non Patent Literature 1 describes a heterojunction field-effect transistor (HFET). The HFET is formed on an m-plane GaN substrate. In the HFET, an undoped GaN layer (1 μm), a Fe-doped GaN layer (1.5 μm), an undoped GaN layer (300 nm) as a channel layer, and an AlGaN layer (undoped AlGaN layer (2 nm), Si-doped AlGaN layer (15 nm), and an undoped AlGaN layer (6 nm)) as a barrier layer are stacked on an m-plane GaN substrate in this order to implement an enhancement (normally-off) HFET.

Non Patent Literature 2 describes a high electron mobility transistor (HEMT). In the HEMT, an AlN buffer layer, an AlGaN channel layer, and an AlGaN barrier layer are stacked on a sapphire substrate in this order.

Non Patent Literature 3 describes, as a method for growing a GaN crystal on a SiC substrate, a method in which AlN is grown on a SiC substrate and then a GaN crystal is grown and another method in which AlN and AlGaN are grown on a SiC substrate and then GaN is grown.

### CITATION LIST

### Non Patent Literature

Non Patent Literature 1: Tetsuya Fujiwara et al., “Enhancement-Mode m-plane AlGaN/GaN Heterojunction Field-Effect Transistors”, Applied Physics Express, Vol. 2, 011001 (2009)

Non Patent Literature 2: Takuma Nanjo et al., “Remarkable breakdown voltage enhancement in AlGaN channel high electron mobility transistors”, Applied Physics Letters, Vol. 92, 263502 (2008)

Non Patent Literature 3: Y. S. Cho et al., “Reduction of stacking fault density in m-plane GaN grown on SiC”, Applied Physics Letters, Vol. 93, 111904 (2008)

### SUMMARY OF INVENTION

### Technical Problem

Electronic devices using gallium nitride-based semiconductors as their materials, such as HEMTs, hold great promise because of high breakdown field strength and high mobility in two-dimensional electron gas channels. To make such an electronic device, typically a channel layer and a barrier layer of group III nitride-based semiconductors are grown on a GaN substrate as described in Non Patent Literature 1.

On the other hand, group III nitride-based semiconductors containing Al, for example AlN, have larger bandgaps than GaN and higher breakdown field strengths. Accordingly, an electronic device having a higher withstand voltage and higher output can be made by using a substrate made of a group III nitride-based semiconductor containing Al.

In Non Patent Literature 2, an AlN buffer layer, an AlGaN channel layer, and an AlGaN barrier layer are grown in a c-axis direction. In this case, a piezo electric field produces a highly-concentrated two-dimensional electron gas in the AlGaN channel layer even in a nonoperational state. Accordingly, it is difficult to implement a normally-off semiconductor device.

Furthermore, in Non Patent Literatures 2 and 3, a group III nitride-based semiconductor layer containing Al is grown on a substrate made of a material that is not a group III nitride, for example a SiC substrate. In this case, it is difficult to minimize occurrence of crystal defects in the semiconductor layer.

The present invention has been made in light of these problems and an object of the present invention is to provide a normally-off group III nitride semiconductor device having high breakdown field strength and minimal crystal defects. Another object of the present invention is to provide a group III nitride laminated semiconductor wafer used to make the group III nitride semiconductor device.

### Solution to Problem

A group III nitride laminated semiconductor wafer according to one aspect of the present invention includes: (a) a substrate which is made of AlN and has a main surface along a c-axis of the AlN crystal, (b) a first semiconductor layer which is made of a group III nitride-based semiconductor containing Al and is provided on the main surface, and (c) a second semiconductor layer which is provided on the main surface, is made of a group III nitride-based semiconductor having a larger bandgap than the first semiconductor layer, and forms a heterojunction with the first semiconductor layer.

A group III nitride semiconductor device according to another aspect of the present invention includes: (a) a substrate which is made of AlN and has a main surface along a c-axis of the AlN crystal, (b) a channel layer which is made of a group III nitride-based semiconductor containing Al and is provided on the main surface, and (c) a first barrier layer which is provided on the main surface, is made of a group III nitride-based semiconductor having a larger bandgap than the first semiconductor layer, and forms a heterojunction with the channel layer.

The group III nitride laminated semiconductor wafer and the group III nitride semiconductor device use as its substrate an AlN substrate that has a high breakdown field strength than a GaN substrate. The AlN substrate has a main surface along a c-axis. The main surface is a nonpolar surface, for example an m-plane or an a-plane. A channel layer and a first semiconductor layer of group III nitride-based semiconductors containing Al are formed on the main surface. The channel layer and the first semiconductor layer thus formed on the nonpolar surface can reduce piezo electric fields and therefore can minimize occurrence of a two-dimensional electron gas which would be caused by piezo electric fields in the channel layer and the first semiconductor layer. Accordingly, a normally-off semiconductor device can be advantageously implemented. Furthermore, because first and second semiconductor layers of group III nitride-based semiconductors are formed on the AlN substrate, which is a group III nitride substrate, occurrence of crystal defects in these semiconductor layers can be advantageously minimized. Alternatively, because the channel layer and the barrier layer of group III nitride-based semiconductors are formed on the MN substrate, which is a group III nitride substrate, occurrence of crystal defects in the semiconductor layers can be advantageously minimized. In this way, the group III nitride laminated semiconductor wafer and the group III nitride semiconductor device can provide a normally-off semiconductor device having high breakdown field strength and minimal crystal defects and a laminated wafer used to make the semiconductor device.

In the group III nitride laminated semiconductor wafer, an X-ray rocking curve half width of the group III nitride-based semiconductor containing Al in the c-axis direction in the first semiconductor layer can be less than or equal to 1.2 times an X-ray rocking curve half width of the group III nitride-based semiconductor in the direction perpendicular to the c-axis. In the group III nitride semiconductor device, an X-ray rocking curve half width of the group III nitride-based semiconductor containing Al in the direction of c-axis in the channel layer can be less than or equal to 1.2 times an X-ray rocking curve half width of the group III nitride-based semiconductor in the direction perpendicular to the c-axis.

In the group III nitride laminated semiconductor wafer, the main surface can be an m-plane or a-plane of the AlN crystal. In the group III nitride semiconductor device, the main surface can be the m-plane or a-plane of the AlN crystal. By using such a nonpolar surface as the main surface of the AlN substrate, Piezo electric fields which would be produced in the channel layer and the first semiconductor layer can be effectively reduced.

In the group III nitride laminated semiconductor wafer, the thickness of the first semiconductor layer can be less than or equal to 50 nm. The thickness of the channel layer of the group III nitride semiconductor device can be less than or equal to 50 nm. The inventor has conducted studies and found that when the channel layer and the first semiconductor layer that contain Al are too thick, anisotropy is caused in fluctuations in crystal direction and affects device characteristics. Specifically, as the thicknesses of the channel layer and the first semiconductor layer increase, fluctuations in crystal in the c-axis direction increase as compared with fluctuations in the direction orthogonal to the c-axis direction and stacking faults extend mainly in the direction orthogonal to the c-axis direction. As a result, flow of current in the direction orthogonal to the direction in which the stacking faults extend is inhibited and device resistance increases. Furthermore, leak current flows through the staking faults in the direction parallel to the direction in which the stacking faults extend, decreasing withstand voltage characteristics. There is another problem that device characteristics of a transistor made such as leak current, forward current, and on-resistance in the c-axis direction differ from those in the direction orthogonal to the c-axis direction. By forming both of the channel layer and the first semiconductor layer to a thickness of less than or equal to 50 nm, such anisotropy of fluctuations in the crystal directions can be minimized to maintain good device characteristics.

In the group III nitride laminated semiconductor wafer, the first semiconductor layer can be made of AlGaN. The channel layer of the group III nitride semiconductor device can be made of AlGaN.

In the group III nitride laminated semiconductor wafer, the second semiconductor layer can be made of AlN. In the group III nitride semiconductor device, the first barrier layer can be made of AlN.

The group III nitride laminated semiconductor wafer may further include a third semiconductor layer. The third semiconductor layer is provided in a position on the main surface so as to sandwich the first semiconductor layer between itself and the second semiconductor layer, is made of a group III nitride-based semiconductor having a larger bandgap than the first semiconductor layer, and forms a heterojunction with the first semiconductor layer. The group III nitride semiconductor device can further include a second barrier layer. The second barrier layer is provided in a position on the main surface so as to sandwich the channel layer between itself and the first barrier layer, is made of a group III nitride-based semiconductor having a larger bandgap than the channel layer, and forms a heterojunction with the channel layer. Thus, a so-called double-hetero-structure transistor can be advantageously implemented.

In the group III nitride laminated semiconductor wafer, the third semiconductor layer can be made of AlN. In the group III nitride semiconductor device, the second barrier layer can be made of AlN.

These and other objects, features and advantages of the aspects of the present invention will be more readily understood from the following detailed description of preferred embodiments of the present invention, taken in conjunction with the accompanying drawings.

### Advantageous Effects of Invention

According to one aspect of the present invention, a normally-off group III nitride semiconductor device having high breakdown field strength and minimal crystal defects is provided. Furthermore, a group III nitride laminated semiconductor wafer used to make the group III nitride semiconductor device is provided.

### BRIEF DESCRIPTION OF DRAWINGS

FIG. 1 is a diagram illustrating a structure of a group III nitride laminated semiconductor wafer according to a first embodiment;

FIG. 2 is a diagram illustrating a structure of a group III nitride laminated semiconductor wafer according to a second embodiment;

FIG. 3 is a diagram illustrating a structure of a group III nitride laminated semiconductor wafer according to a third embodiment;

FIG. 4 is a diagram illustrating a structure of a group III nitride laminated semiconductor wafer C, which is a comparative example;

FIG. 5 is a table showing results of evaluation in Example 1;

FIG. 6 is a diagram illustrating a placement of a source electrode S, a gate electrode G, and a drain electrode D;

FIG. 7 is a table showing results of evaluation in Example 2;

FIG. 8 is a table showing results of result in Example 3;

FIG. 9 is a table showing results of result in Example 4;

FIG. 10 is a diagram illustrating a structure of a group III nitride semiconductor device according to a fourth embodiment; and

FIG. 11 is a diagram illustrating a structure of a group III nitride semiconductor device according to a fifth embodiment.

### DESCRIPTION OF EMBODIMENTS

Embodiments of a group III nitride laminated semiconductor wafer and a group III nitride semiconductor device according to the present invention will be described in detail with reference to the accompanying drawings. In the description of the drawings, like elements are given like reference numerals and repeated description of those elements will be omitted.

### First Embodiment

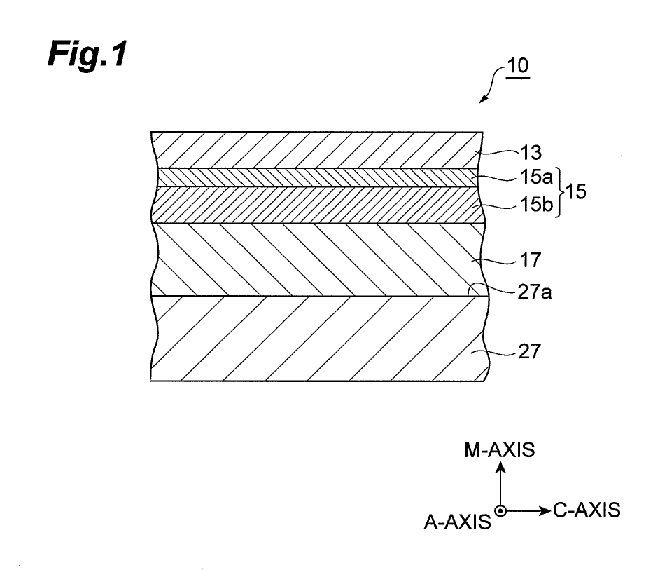

FIG. 1 is a diagram illustrating a structure of a group III nitride laminated semiconductor wafer according to a first embodiment of the present invention. The group III nitride laminated semiconductor wafer 10 of this embodiment includes an AlN substrate 27. The AlN substrate 27 has a main surface 27a along a c-axis of the AlN crystal. FIG. 1 illustrates the c-axis direction and m-axis direction of the AlN substrate 27. In this embodiment, the main surface 27a of the AlN substrate 27 is formed by an m-plane of the AlN crystal.

The group III nitride laminated semiconductor wafer 10 includes a first Al_{X1}In_{Y1}Ga_{1-X1-Y1}N (0<X1≧1, 0≦Y1<1, 0<X1+Y1≦1) layer 13 as a first semiconductor layer made of a group III nitride semiconductor containing Al, and an Al_{X2}In_{Y2}Ga_{1-X2-Y2}N (0≦X2≦1, 0≦Y2≦1, 0<X2+Y2≦1) layer 15 as a second semiconductor layer made of a group III nitride semiconductor. The second Al_{X2}In_{Y2}Ga_{1-X2-Y2}N layer 15 is provided on the main surface 27a of the AlN substrate 27 and the first Al_{X1}In_{Y1}Ga_{1-X1-Y1}N layer 13 is provided on the second Al_{X2}In_{Y2}Ga_{1-X2-Y2}N layer 15. The second Al_{X2}In_{Y2}Ga_{1-X2-Y2}N layer 15 has a larger bandgap than the first Al_{X1}In_{Y1}Ga_{1-X1-Y1}N layer 13 and forms a heterojunction with the first Al_{X1}In_{Y1}Ga_{1-X1-Y1}N layer 13. In a semiconductor device made from the group III nitride laminated semiconductor wafer 10, the first Al_{X1}In_{Y1}Ga_{1-X1-Y1}N layer 13 functions as a channel layer, for example, and the second Al_{X2}In_{Y2}Ga_{1-X2-Y2}N layer 15 functions as a barrier layer. The second Al_{X2}In_{Y2}Ga_{1-X2-Y2}N layer 15 includes an undoped layer 15a adjacent to the first Al_{X1}In_{Y1}Ga_{1-X1-Y1}N layer 13 and a doped layer 15b. The doped layer 15b is doped with Si, for example.

The first Al_{X1}In_{Y1}Ga_{1-X1-Y1}N layer 13 can be made of AlGaN (specifically, Y1=0 and 0<X1<1). The second Al_{X2}In_{Y2}Ga_{1-X2-Y2}N layer 15 can be made of AlN (specifically, X2=1, Y2=0). The first Al_{X1}In_{Y1}Ga_{1-X1-Y1}N layer 13 and the second Al_{X2}In_{Y2}Ga_{1-X2-Y2}N layer 15 are grown by metal-organic-vapor-phase epitaxy (MOVPE), for example.

In a preferred example, the first Al_{X1}In_{Y1}Ga_{1-X1-Y1}N layer 13 has a thickness of 30 nm, for example, an Al atomic ratio X1 of 0.8, and an In atomic ratio Y1 of 0. The second Al_{X2}In_{Y2}Ga_{1-X2-Y2}N layer 15 has a thickness of 23 nm, for example (the undoped layer 15a is 3 nm thick and the doped layer 15b is 20 nm thick) and the doped layer 15b has a dopant concentration of 1×10¹⁹ cm⁻³.

The second Al_{X2}In_{Y2}Ga_{1-X2-Y2}N layer 15 is provided on an epitaxial layer 17 as a buffer layer. The epitaxial layer 17 is made of an undoped group III nitride-based semiconductor, for example undoped AlN. The epitaxial layer 17 is provided on the main surface 27a of the AlN substrate 27. A preferred thickness of the epitaxial layer 17 is 2 μm, for example. The epitaxial layer 17 is grown by metal-organic-vapor-phase epitaxy, for example.

A method for fabricating the group III nitride laminated semiconductor wafer 10 of this embodiment is as described below. First, an AlN substrate 27 having a main surface (preferably an m-plane or an a-plane) 27a along a c-axis is set in a MOVPE furnace and is subjected to furnace heat treatment in an atmosphere of NH₃ at 115° C. Then, MOVPE is used to grow an epitaxial layer 17, a doped layer 15b and an undoped layer 15a of a second Al_{X2}In_{Y2}Ga_{1-X2-Y2}N layer 15, and a first Al_{X1}In_{Y1}Ga_{1-X1-Y1}N layer 13 in order. The AlN substrate 27 used here is preferably one that has an excellent crystallinity such as a dislocation density at the main surface 27a less than 1×10⁶ cm⁻².

In the group III nitride laminated semiconductor wafer 10 of this embodiment, an AlN substrate 27 that has a higher breakdown field strength than a GaN substrate is used as its substrate. The main surface 27a of the AlN substrate 27 is formed by the m-plane of the AlN crystal and the first Al_{X1}In_{Y1}Ga_{1-X1-Y1}N layer 13 is formed on the main surface 27a. The formation of the first Al_{X1}In_{Y1}Ga_{1-X1-Y1}N layer 13 on the nonpolar surface in this way can reduce piezo electric fields and minimize occurrence of two-dimensional electron gas caused by piezo electric fields in the first Al_{X1}In_{Y1}Ga_{1-X1-Y1}N layer 13 as a channel layer. Accordingly, a normally-off semiconductor device can be advantageously implemented. Furthermore, since the first Al_{X1}In_{Y1}Ga_{1-X1-Y1}N layer 13 and the second Al_{X2}In_{Y2}Ga_{1-X2-Y2}N layer 15 of group III nitride-based semiconductors are formed on the AlN substrate 27, which is a group III nitride substrate, occurrence of crystal defects in the semiconductor layers can be advantageously minimized.

While the main surface 27a of the AlN substrate 27 illustrated in this embodiment is the m-plane, the main surface 27a may be another nonpolar surface such as the a-plane, for example, provided that the main surface 27a extends along the c-axis of an AlN crystal. The advantageous effects of this embodiment described above can be achieved in that case as well.

### Second Embodiment

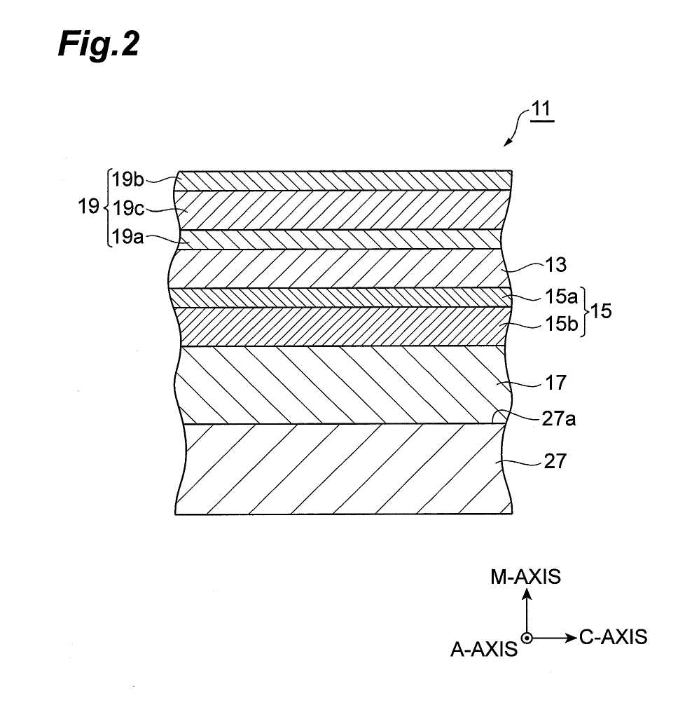

FIG. 2 is a diagram illustrating a structure of a group III nitride laminated semiconductor wafer according to a second embodiment of the present invention. The group III nitride laminated semiconductor wafer 11 of this embodiment includes a first Al_{X1}In_{Y1}Ga_{1-X1-Y1}N layer 13, a second Al_{X2}In_{Y2}Ga_{1-X2-Y2}N layer 15, an epitaxial layer 17, and an AlN substrate 27. These components are the same as those of the first embodiment described above.

The group III nitride laminated semiconductor wafer 11 further includes a third Al_{X3}In_{Y3}Ga_{1-X3-Y3}N (0≦X3≦1, 0≦Y3≦1, 0<X3+Y3≦1) layer 19. The third Al_{X3}In_{Y3}Ga_{1-X3-Y3}N layer 19 is provided in a position so as to sandwich the first Al_{X1}In_{Y1}Ga_{1-X1-Y1}N layer 13 between itself and the second Al_{X2}In_{Y2}Ga_{1-X2-Y2}N layer 15 and is provided, in this embodiment, on the first Al_{X1}In_{Y1}Ga_{1-X1-Y1}N layer 13. The third Al_{X3}In_{Y3}Ga_{1-X3-Y3}N layer 19 has a larger bandgap than the first Al_{X1}In_{Y1}Ga_{1-X1-Y1}N layer 13 and forms a heterojunction with the first Al_{X1}In_{Y1}Ga_{1-X1-Y1}N layer 13. In a semiconductor device made from the group III nitride laminated semiconductor wafer 11, the first Al_{X1}In_{Y1}Ga_{1-X1-Y1}N layer 13 functions as a channel layer, for example, the second Al_{X2}In_{Y2}Ga_{1-X2-Y2}N layer 15 functions as a first barrier layer, and the third Al_{X3}In_{Y3}Ga_{1-X3-Y3}N layer 19 functions as a second barrier layer. The third _{Al}_{X3}In_{Y3}Ga_{1-X3-Y3}N layer 19 includes an undoped layer 19a adjacent to the first Al_{X1}In_{Y1}Ga_{1-X1-Y1}N layer 13, an undoped layer 19b away from the first Al_{X1}In_{Y1}Ga_{1-X1-Y1}N layer 13, and a doped layer 19c provided between the undoped layers 19a and 19b. The doped layer 19c is doped with Si, for example.

In this example as well, the first Al_{X1}In_{Y1}Ga_{1-X1-Y1}N layer 13 can be made of AlGaN and the second A_{X2}In_{Y2}Ga_{1-X2-Y2}N layer 15 can be made of AlN. The third Al_{X3}In_{Y3}Ga_{1-X3-Y3}N layer 19 can be made of AlN. The third _{Al}_{X3}In_{Y3}Ga_{1-X1-Y3}N layer 19 is grown by metal-organic-vapor-phase epitaxy (MOVPE), for example.

In a preferred example, the thickness of the third Al_{X3}In_{Y3}Ga_{1-X3-Y3}N layer 19 is 26 nm, for example, and in one example, each of the undoped layers 15a and 15b is 3 nm thick and the doped layer 19c is 20 nm thick. The dopant concentration of the doped layer 19c is 1×10¹⁹ cm⁻³, for example.

A method for fabricating the group III nitride laminated semiconductor wafer 11 of this embodiment is the same as that of the first embodiment, except that, after first Al_{X1}In_{Y1}Ga_{1-X1-Y1}N layer 13 has been grown, the undoped layer 19a, the doped layer 19c and the undoped layer 19b of the third Al_{X3}In_{Y3}Ga_{1-X3-Y3}N layer 19 are continuously grown by MOVPE. In this embodiment as well, the AlN substrate 27 is preferably one that has an excellent crystallinity such as a dislocation density at the main surface 27a less than 1×10⁶ cm⁻².

Since the group III nitride laminated semiconductor wafer 11 of this embodiment includes the AlN substrate 27, the first Al_{X1}In_{Y1}Ga_{1-X1-Y1}N layer 13, and the second Al_{X2}In_{Y2}Ga_{1-X2-Y2}N layer 15 that are similar to those of the first embodiment, a normally-off semiconductor device having a high breakdown field strength and minimal crystal defects can be made from the group III nitride laminated semiconductor wafer 11.

The group III nitride laminated semiconductor wafer 11 of this embodiment further includes the third Al_{X3}In_{Y3}Ga_{1-X3-Y3}N layer 19. The third Al_{X3}In_{Y3}Ga_{1-X3-Y3}N layer 19 is provided in a position to sandwich the first Al_{X1}In_{Y1}Ga_{1-X1-Y1}N layer 13 between itself and the second Al_{X2}In_{Y2}Ga_{1-X2-Y2}N layer 15, has a larger bandgap than the first Al_{X1}In_{Y1}Ga_{1-X1-Y1}N layer 13, and forms a heterojunction with the first Al_{X1}In_{Y1}Ga_{1-X1-Y1}N layer 13. Since such third Al_{X3}In_{Y3}Ga_{1-X3-Y3}N layer 19 is provided, a transistor with a so-called double-hetero-structure can be advantageously made.

### Third Embodiment

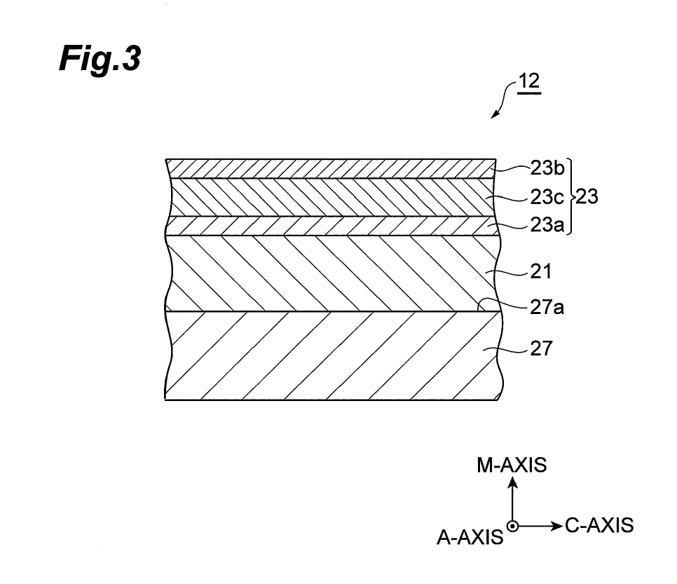

FIG. 3 is a diagram illustrating a structure of a group III nitride laminated semiconductor wafer according to a third embodiment of the present invention. The group III nitride laminated semiconductor wafer 12 of this embodiment includes a first A_{1X}In_{Y1}Ga_{1-X1-Y1}N (0<X1≦1, 0≦Y1<1, 0<X1+Y1≦1) layer 21 as a first semiconductor layer made of a group III nitride semiconductor containing Al, a second Al_{X2}In_{Y2}Ga_{1-X2-Y2}N (0<X2≦1, 0≦Y2 M 1, 0<X2 +Y2≦1) layer 23 as a second semiconductor layer made of a group III nitride semiconductor, and an AlN substrate 27. The AlN substrate 27 has the same configuration as that of the first embodiment described above.

The first Al_{X1}In_{Y1}Ga_{1-X1-Y1}N layer 21 is provided directly on the main surface 27a of the AlN substrate 27 and the second Al_{X2}In_{Y2}Ga_{1-X2-Y2}N layer 23 is provided on the first Al_{X1}In_{Y1}Ga_{1-X1-Y1}N layer 21. The second Al_{X2}In_{Y2}Ga_{1-X2-Y2}N layer 23 has a larger bandgap than the first Al_{X1}In_{Y1}Ga_{1-X1-Y1}N layer 21 and forms a heterojunction with the first Al_{X1}In_{Y1}Ga_{1-X1-Y1}N layer 21. In a semiconductor device made from the group III nitride laminated semiconductor wafer 12, the first Al_{X1}In_{Y1}Ga_{1-X1-Y1}N layer 21 functions as a channel layer, for example, and the second Al_{X2}In_{Y2}Ga_{1-X2-Y2}N layer 23 functions as a barrier layer, for example. The second Al_{X2}In_{Y2}Ga_{1-X2-Y2}N layer 23 includes an undoped layer 23a adjacent to the first Al_{X1}In_{Y1}Ga_{1-X1-Y1}N layer 21, an undoped layer 23b away from the first Al_{X1}In_{Y1}Ga_{1-X1-Y1}N layer 21, and a doped layer 23c provided between the undoped layers 23a and 23b. The doped layer 23c is doped with Si, for example.

The first Al_{X1}In_{Y1}Ga_{1-X1-Y1}N layer 21 can be made of AlGaN (specifically, Y1=0, 0<X1<1). The second Al_{X2}In_{Y2}Ga_{1-X2-Y2}N layer 23 can be made of AlN (specifically, X2=1, Y2=0). The first Al_{X1}In_{Y1}Ga_{1-X1-Y1}N layer 21 and the second Al_{X2}In_{Y2}Ga_{1-X2-Y2}N layer 23 is grown by metal-organic-vapor-phase epitaxy (MOVPE), for example.

In a preferred example, the first Al_{X1}In_{Y1}Ga_{1-X1-Y1}N layer 21 has a thickness of 2 μm, for example, an Al atomic ratio X1 of 0.8, and an In atomic ratio Y1 of 0. The second Al_{X2}In_{Y2}Ga_{1-X2-Y2}N layer 23 is 36 nm thick, for example, and in one example, each of the undoped layers 23a and 23b are 3 nm, and the doped layer is 30 nm thick. The doped layer 23c has a dopant concentration of 1×10¹⁹ cm⁻³.

A method for fabricating the group III nitride laminated semiconductor wafer 12 of this embodiment is as described below. First, an AlN substrate 27 is subjected to furnace heat treatment in an atmosphere of NH₃ at 1150° C. Then, MOVPE is used to grow a first Al_{X1}In_{Y1}Ga_{1-X1-Y1}N layer 21, an undoped layer 23a, a doped layer 23c and an undoped layer 23b of a second Al_{X2}In_{Y2}Ga_{1-X2-Y2}N layer 23 in order. In this embodiment as well, the AlN substrate 27 is preferably one that has an excellent crystallinity such as a dislocation density at the main surface 27a less than 1×10⁶ cm⁻².

### EXAMPLE 1

Here, results of evaluation of crystallinity of the group III nitride laminated semiconductor wafer 10 of the first embodiment (see FIG. 1) and the group III nitride laminated semiconductor wafer 12 of the third embodiment (see FIG. 3) fabricated will be described.

In this example, two AlN substrates having a main surface which is an m-plane and a dislocation density of less than 1×10⁶ cm⁻² were provided. A 2-μm-thick undoped AlN layer, which corresponds to an epitaxial layer 17, a 20-nm-thick Si-doped layer with a dopant concentration of 1×10¹⁹ cm⁻³, which corresponds to the doped layer 15b, a 3-nm-thick undoped AlN layer, which corresponds to the undoped layer 15a, a 30-nm-thick undoped Al_{0.8}Ga_{0.2}N layer, which corresponds to the first Al_{X1}In_{Y1}Ga_{1-X1-Y1}N layer 13, were grown on one of the AlN substrates in order. This wafer will be hereinafter referred to as laminated wafer A. A 2-μm-thick undoped Al_{0.8}Ga_{0.2}N layer, which corresponds to the first Al_{X1}In_{Y1}Ga_{1-X1-Y1}N layer 21, a 3-nm-thick undoped AlN layer, which corresponds to the undoped layer 23a, a 30-nm-thick undoped AlN layer, which corresponds to the doped layer 23c, and a 3-nm-thick undoped AlN layer, which corresponds to the undoped layer 23b, were grown on the other AlN substrate in order. This wafer will be hereinafter referred as laminated wafer B.

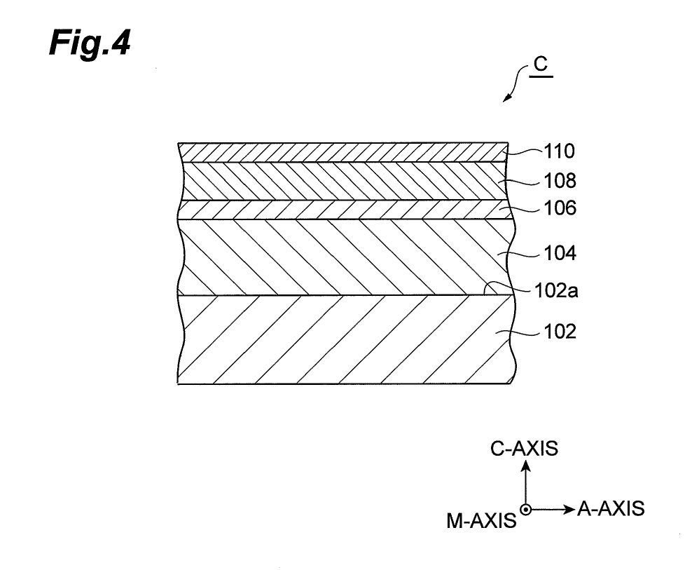

A group III nitride laminated semiconductor wafer C illustrated in FIG. 4 was made as a comparative example. The group III nitride laminated semiconductor wafer C illustrated in FIG. 4 includes an AlN substrate 102 having a main surface 102a which is a c-plane of an AlN crystal and includes a 2-μm-thick undoped Al_{0.8}Ga_{0.2}N layer 104, a 3-nm-thick undoped AlN layer 106, a 30-nm-thick Si-doped AlN layer 108 having a dopant concentration of 1×10¹⁹ cm⁻³, and a 3-nm-thick undoped AlN layer 110 stacked on the main surface 102a. As in the laminated wafers A and B, the AlN substrate 102 has an excellent crystallinity with a dislocation density at the main surface of less than 1×10⁶ cm⁻².

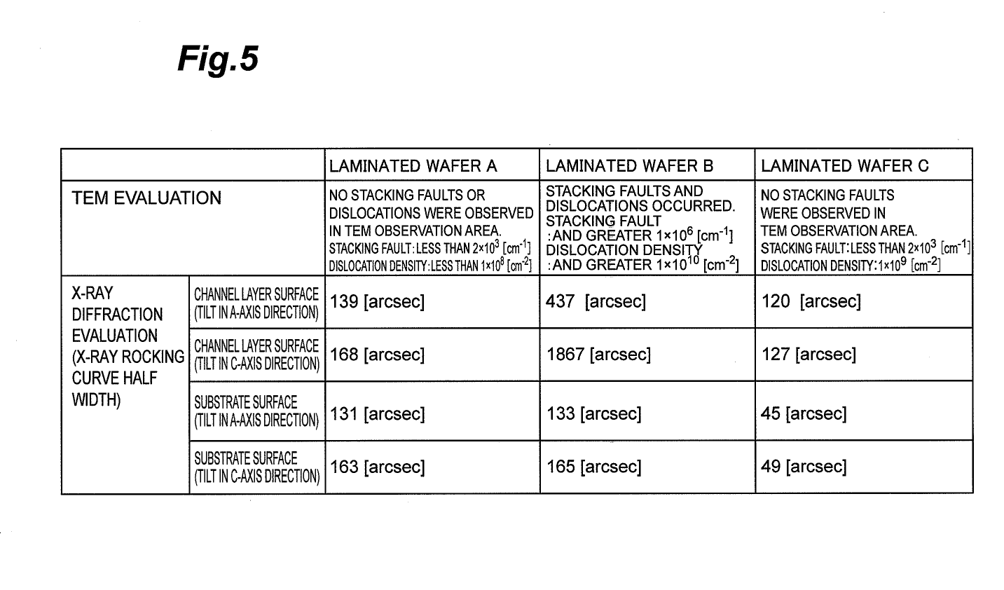

FIG. 5 is a table showing the results of the evaluation in this example. FIG. 5 shows observed stacking faults and dislocations in above-described laminated wafers A to C observed under a transmission electron microscope (TEM). FIG. 5 also shows X-ray rocking curve (XRC) half width values that depend on tilts, i.e., fluctuations, in the a-axis and c-axis directions at the surface of the channel layer (that is, undoped Al_{0.8}Ga_{0.2}N layer) and the surface of the AlN substrate of each of laminated wafers A to C. Note that for laminated wafer C, XRC half width values that depend on tilts in the m-axis direction is shown.

As shown in FIG. 5, many stacking faults and dislocations occurred in laminated wafer B, and the TEM observations indicate a stacking fault density of greater than or equal to 1×10⁶ cm⁻¹ and a dislocation density of greater than or equal to 1×10¹⁰ cm⁻¹. There occurred stacking faults and dislocations. In particular, the stacking faults occurred presumably because the thick (2 μm) undoped Al_{0.8}Ga_{0.2}N layer stacked on the AlN substrate increased fluctuations in the crystal in the c-axis direction compared with fluctuations in the direction orthogonal to the c-axis direction, which caused stacking faults to extend primarily in the direction orthogonal to the c-axis direction. Furthermore, the XRC half widths of the channel layer (the undoped Al_{0.8}Ga_{0.2}N layer) are large as compared with the XRC half widths of the AlN substrate and the XRC half width of the channel layer in the c-axis direction is remarkably larger than the XRC half width in the a-axis direction. Thus, anisotropy occurred in crystal tilts, i.e., fluctuations.

On the other hand, the TEM observations have shown no stacking faults or dislocations in laminated wafer A. The TEM observations indicate a stacking fault density of less than 2×10³ cm⁻¹ and a dislocation density of less than 1×10⁸ cm⁻¹. No stacking fault or dislocations have occurred and the XRC half widths of the channel layer (the undoped Al_{0.8}Ga_{0.2}N layer) were about the same as those of the AlN substrate, thus there was not anisotropy in the a-axis and C-axis directions. This is presumably because the channel layer (the undoped Al_{0.8}Ga_{0.2}N layer) in laminated wafer A is formed thinner (30 nm) than that of laminated wafer B. In this way, to achieve a better crystallinity of the channel layer, the channel layer is preferably formed thin. For example, forming the channel layer to a thickness less than or equal to 50 nm can effectively reduce stacking faults and dislocations in the channel layer and minimize anisotropy of crystal tilts, i.e., fluctuations. The lower limit of the thickness of the channel layer (the undoped Al_{0.8}Ga_{0.2}N layer) is 2 nm, for example.

In laminated wafer C, while dislocations with a dislocation density of 1×10⁹ cm⁻¹ occurred in the channel layer (the undoped Al_{0.8}Ga_{0.2}N layer), cross-sectional TEM observations have not shown stacking faults. That is, the stacking fault density is less than 2×10³ cm⁻¹. The XRC half widths of the channel layer in the a-axis and m-axis directions were similar to each other and thus there was not anisotropy of crystal tilts, i.e. fluctuations.

The group III nitride laminated semiconductor wafer 10 of the first embodiment (laminated wafer A in this example) has a so-called inverted HEMT structure. The group III nitride laminated semiconductor wafer 11 of the second embodiment has a double-hetero HEMT structure. Laminated wafer A which has the inverted HEMT structure has advantages, including the ease of forming an ohmic junction as compared to laminated wafer C of this example which has the normal HEMT structure.

Laminated wafer B for a double hetero structure HEMT is characterized by a high carrier confinement effect because the channel layer is confined between the barrier layers above and below the channel layer. By exploiting the carrier confinement effect, the conductivity of the channel layer can be increased, in other words, sheet resistance can be reduced. Furthermore, the withstand voltage of a device can be improved because portions in contact with electrodes are made of a material having a larger bandgap.

### EXAMPLE 2

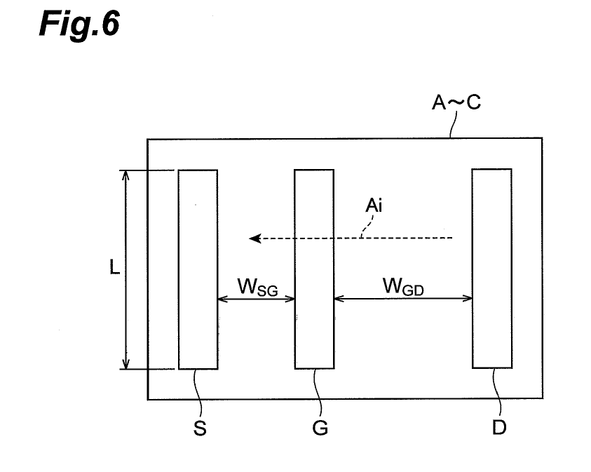

HFET structures were made using laminated wafers A to C of Example 1 and forward current characteristics and leak current characteristics of the HFET structures were studied. The results of the study will be described. In this example, a source electrode S, a gate electrode and a drain electrode D were formed on laminated wafers A to C as illustrated in FIG. 6. The electrodes S, G and D were formed so that the current direction Ai is along the a-axis direction in a certain region on laminated wafers A to C. In the other regions on laminated wafers A to C, the electrodes S, G and D were formed so that the current direction Ai is along the c-axis direction (the m-axis direction on laminated wafer C).

In this example, the lengths L of the electrodes S, G and D in the longitudinal direction (the direction orthogonal to the direction in which the electrodes S, G and D are arranged) were all 1000 μm and the distance W_{SG} between the source electrode S and the gate electrode G was 4 μm, and the distance W_{GD} between the gate electrode G and the drain electrode D was 10 μm. The semiconductor layer surrounding the regions including the electrodes S, G and D was removed in the form of mesa by reactive ion etching (RIE) to provide inter-element isolation.

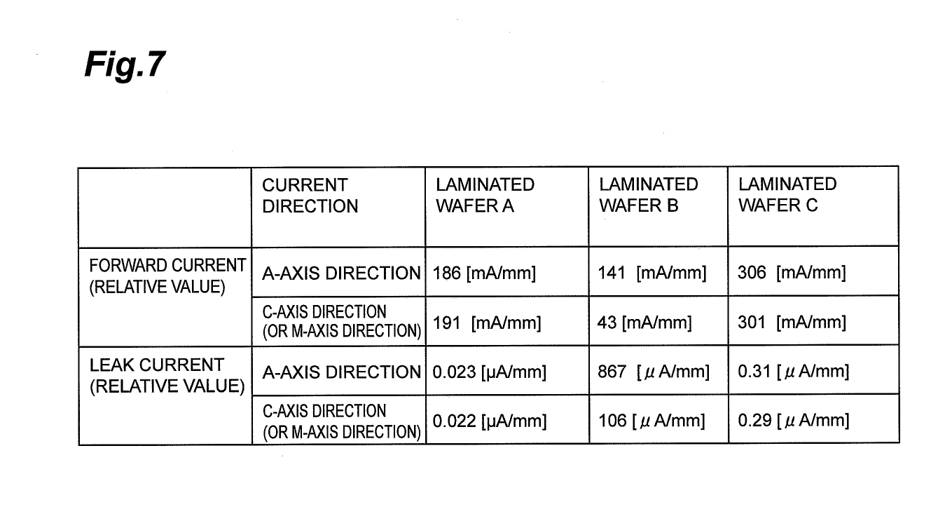

FIG. 7 is a table showing results of evaluation in this example. FIG. 7 shows measured values of drain current (forward current) density when a voltage of +1 V was applied between the source electrode S and the gate electrode G and a voltage of +5 V was applied between the source electrode S and the drain electrode D of each of laminated wafers A to C described above. FIG. 7 also shows measured values of source-drain leak current density when a voltage of −2 V was applied between the source electrode S and the gate electrode G and a voltage of −100 V was applied between the source electrode S and the drain electrode D of each of laminated wafers.

The forward current will be discussed first. As shown in FIG. 7, when the current direction Ai is along the c-axis direction in laminated wafer B, the density of current is lower than that in the a-axis direction. This is presumably because when the current direction Ai is along the c-axis direction in laminated wafer B, the current flows in the direction perpendicular to stacking faults and there is influence of scattering caused by the stacking faults. This means that in such a case, the on-resistance of the element increases.

The leak current will be discussed. As shown in FIG. 7, current density in laminated wafer B is higher when the current direction Ai is along the a-axis direction than when the current direction Ai is along the c-axis direction. This is presumably because when the current direction Ai is along the a-axis direction in laminated wafer B, the current flows in the direction parallel to stacking faults and therefore a large amount of leak current occurs through the stacking faults. This means that in such a case, the withstand voltage of the element decreases.

In contrast to the results for laminated wafer B, the on-resistance of the element can be kept low because the forward current density in laminated wafer A is about the same irrespective of along which crystal axis the current Ai is flowing. Furthermore, the withstand voltage of the element can be kept high regardless of the current direction Ai in laminated wafer A because the leak current density is about the same irrespective of along which crystal axis the current Ai is flowing. These characteristics of laminated wafer A can be attributed to the fact that the channel layer of laminated wafer A has fewer stacking faults and dislocations than the channel layer of laminated wafer B and has significantly less anisotropy of crystal tilts (fluctuations) and better crystallinity.

In laminated wafer C, while dislocations were found in the channel layer, there was not anisotropy of the forward current density and the leak current density.

The results in this example have shown that by forming the channel layer relatively thin (for example less than or equal to 50 nm) as in laminated wafer A to reduce occurrence of stacking faults and dislocations and anisotropy of crystal tilts, i.e., fluctuations, in the channel layer, anisotropy of on-resistance and withstand voltage of a semiconductor device made from the laminated wafer can be effectively minimized.

It should be noted that in Non Patent Literature 3 mentioned above, X-ray rocking curve half widths significantly differ between the c-axis direction and the direction perpendicular to the c-axis. As shown in FIG. 5, the X-ray rocking curve half widths in the c-axis direction and the a-axis direction in laminated wafer A in Example 1 are not exactly equal to each other, but this is because of the influences of measurement errors and the conditions of the laminated wafer, for example the shape, warpage, or cracks. In laminated wafer A in this example, the ratio of the XRC half width in the direction (for example the a-axis) perpendicular to the c-axis direction, 139 aresec (which is equivalent to the angle of tilt to the direction perpendicular to the c-axis), to the XRC half width in the c-axis direction, 168 arcsec (which is equivalent to the angle of tilt to the c-axis direction), is 168/139=1.2. Therefore, it can be said that if the angle of tilt to the c-axis direction is less than or equal to 1.2 times the angle of tilt to the direction perpendicular to the c-axis, the wafer has a good crystallinity as illustrated in Example 2.

### EXAMPLE 3

Examples 1 and 2 described above have shown that when a nonpolar AlN substrate such as an m-plane is used, the anisotropies of the on-resistance and withstand resistance of a semiconductor device made from a laminated wafer can be minimized and the device characteristics can be improved by growing the AlGaN channel layer to a relatively small thickness as in laminated wafer A to reduce occurrence of stacking faults and dislocations and anisotropy of crystal tilts (fluctuations) in the channel layer.

Here, an example regarding the range of thickness of the AlGaN channel layer, which is 30 nm in laminated wafer A in Example 1, will be described.

In this example, in addition to wafer A made in Example 1, laminated wafers A₄₀, A₅₀, A₆₀, A₈₀ and A₂₀₀₀ including AlGaN channel layers having thicknesses of 40 nm, 50 nm, 60 nm, 80 nm and 200 nm, respectively, were made. The configurations of these laminated wafers other than the AlGaN channel layers were exactly the same as that of laminated wafer A in Example 1.

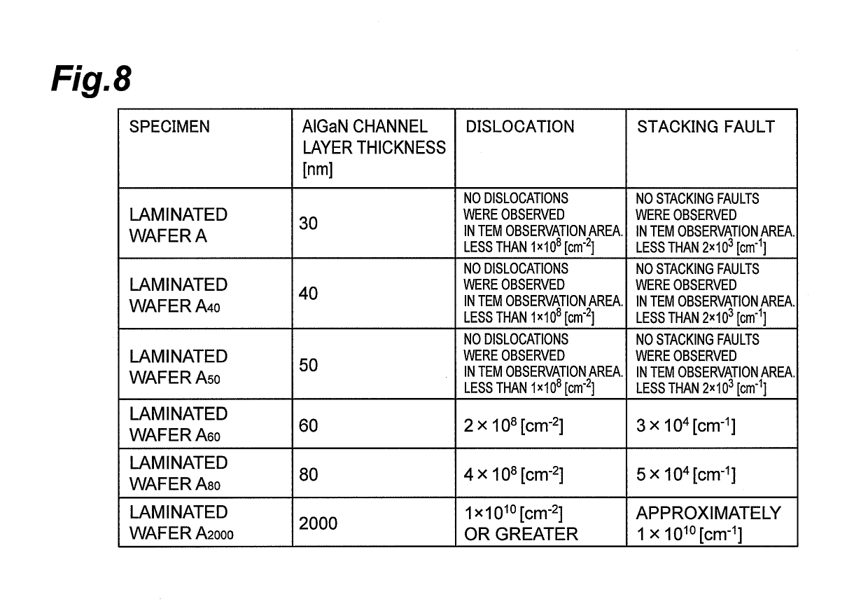

Since it was revealed in Examples 1 and 2 that anisotropy of crystal tilts, i.e., fluctuations, is caused by dislocations and crystal defects such as stacking faults in the AlGaN channel layer, TEM evaluation was performed on laminated wafers A₄₀, A₅₀, A₆₀, A₈₀ and A₂₀₀₀ of this example to study the relationship between crystal defects and the thickness of the AlGaN channel layer. FIG. 8 is a table showing the results. It can be seen from the results shown in FIG. 8 that the thickness of the AlGaN channel layer is preferably less than or equal to 50 nm.

### EXAMPLE 4

It is shown in FIG. 8 illustrating AlGaN layer thicknesses, crystal defects and anisotropies in Example 3 that crystal defects and anisotropy occur when the thickness of the AlGaN channel layer is thicker than 50 nm.

The experiment was continued to study optimization of epitaxial growth, in particular, optimization of a jig (susceptor). The experiment has shown that crystal defects occur even in an AlGaN channel layer that has a thickness of 30 nm, which is the same as the thickness of the AlGaN channel layer of Example 1, when the AlGaN channel layer is not in optimum epitaxial growth conditions. It has been also found that such conditions cause anisotropy of crystal tilts, i.e., fluctuations, and that when the anisotropy of the AlGaN channel layer is small (the hwc/hwa mentioned above is less than or equal to 1.2), good characteristics can be achieved. This example will be described below.

In this example, laminated wafers D to G having the same epitaxial structure as laminated wafer A in Example 1 were made. While the pocket of the susceptor on which a 430-μm-thick AlN substrate was placed was 430 μm thick in Example 1, susceptors with pocket depths of 450 μm, 500 μm, 600 μm and 800 μm were used in this example to conduct experiments in which flow of gas was intentionally disturbed to examine the effect. In doing this, the flow rate of the gas and growth time were adjusted so that the AlGaN channel layers had the same composition and thickness as wafer A of Example 1.

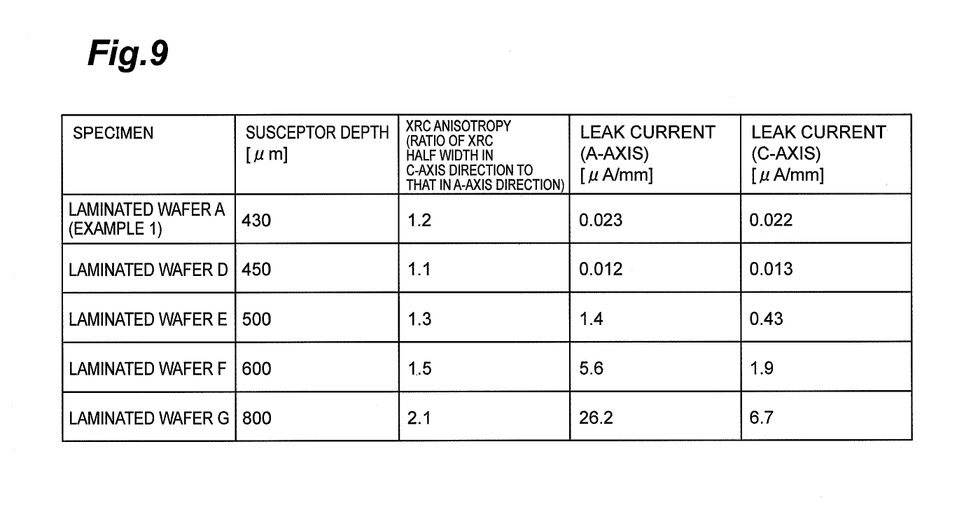

FIG. 9 is a table showing the results of this example. As shown in FIG. 9, some of the specimens with the same epitaxial structure exhibited large anisotropies of XRC half widths while others exhibited small anisotropies. When the ratio of the XRC half widths (hwc/hwa) of the AlGaN channel layer is greater than 1.2, dislocations and stacking faults occur, causing degradations of device characteristics such as increase in leak current and on-resistance as illustrated in FIG. 9.

### Fourth Embodiment

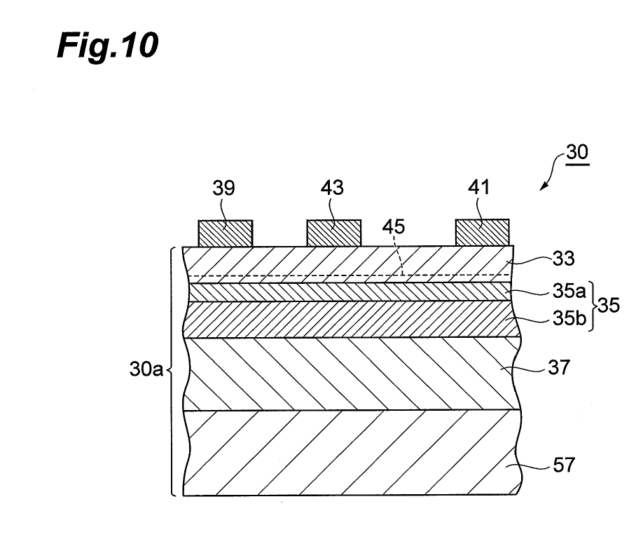

FIG. 10 is a diagram illustrating a structure of a group III nitride semiconductor device according to a fourth embodiment of the present invention. The group III nitride semiconductor device 30 of this embodiment includes a laminated semiconductor part 30a. The laminated semiconductor part 30a is one that was cut in chip form from a group III nitride laminated semiconductor wafer 10 according to the first embodiment (see FIG. 1) and includes a first Al_{X1}In_{Y1}Ga_{1-X1-Y1}N layer 33 as a channel layer, a second Al_{X2}In_{Y2}Ga_{1-X2-Y2}N layer 35 (an undoped layer 35a and a doped layer 35b) as a barrier layer, and an epitaxial layer 37. The layers 33, 35 and 37 have the same configurations as the first Al_{X1}In_{Y1}Ga_{1-X1-Y1}N layer 13, the second Al_{X2}In_{Y2}Ga_{1-X2-Y2}N layer 15, and the epitaxial layer 17, respectively, of the first embodiment and therefore detailed description of these layers will be omitted. The laminated semiconductor part 30a also includes an AlN substrate 57. The AlN substrate 57 has the same configuration as the AlN substrate 27 of the first embodiment.

The group III nitride semiconductor device 30 further includes electrodes 39 and 41 provided side by side on the first Al_{X1}In_{Y1}Ga_{1-X1-Y1}N layer 33. The group III nitride semiconductor device 30 further includes an electrode 43 provided between the electrodes 39 and 41 on the first Al_{X1}In_{Y1}Ga_{1-X1-Y1}N layer 33.

If the group III nitride semiconductor device 30 is a heterojunction transistor, the electrode 39 is one of a source electrode and a drain electrode, the electrode 41 is the other of the source electrode and the drain electrode, and the electrode 43 is a gate electrode. Alternatively, if the group III nitride semiconductor device 30 is a Schottky barrier diode, the electrodes 39 and 41 are anode electrodes and the electrode 43 is a cathode electrode.

In a certain period of operation of the group III nitride semiconductor device 30, a reverse bias is applied to the electrode 43. On the other hand, in another period of operation of the group III nitride semiconductor device 30, a forward bias is applied to the electrode 43. During this operation period, the electrodes 39 and 41 provide carriers to flow through the group III nitride semiconductor device 30. Therefore, the electrodes 39 and 41 preferably form ohmic junctions with the first Al_{X1}In_{Y1}Ga_{1-X1-Y1}N layer 33. Furthermore, the electrode preferably forms a Schottky junction with the first Al_{X1}In_{Y1}Ga_{1-X1-Y1}N layer 33. In the group III nitride semiconductor device 30, the heterojunction between the first Al_{X1}In_{Y1}Ga_{1-X1-Y1}N layer and the second Al_{X2}In_{Y2}Ga_{1-X2-Y2}N layer 35 produces a two-dimensional electron gas layer 45 inside the first Al_{X1}In_{Y1}Ga_{1-X1-Y1}N layer 33.

The group III nitride semiconductor device 30 of this embodiment includes the laminated semiconductor part 30a having the same configuration as the group III nitride laminated semiconductor wafer 10 of the first embodiment. Accordingly, the group III nitride semiconductor device 30 can provide a normally-off semiconductor device having high breakdown field strength and minimal crystal defects.

As described with respect to the first and second embodiments, the first Al_{X1}In_{Y1}Ga_{1-X1-Y1}N layer 33, which is a channel layer, is preferably a thin layer having a thickness of less than or equal to 50 nm, for example, in this embodiment as well. This can minimize the anisotropy of fluctuations in the crystal direction of the first Al_{X1}In_{Y1}Ga_{1-X1-Y1}N layer 33 to maintain good device characteristics, in particular, good withstand voltage and on-resistance.

### Fifth Embodiment

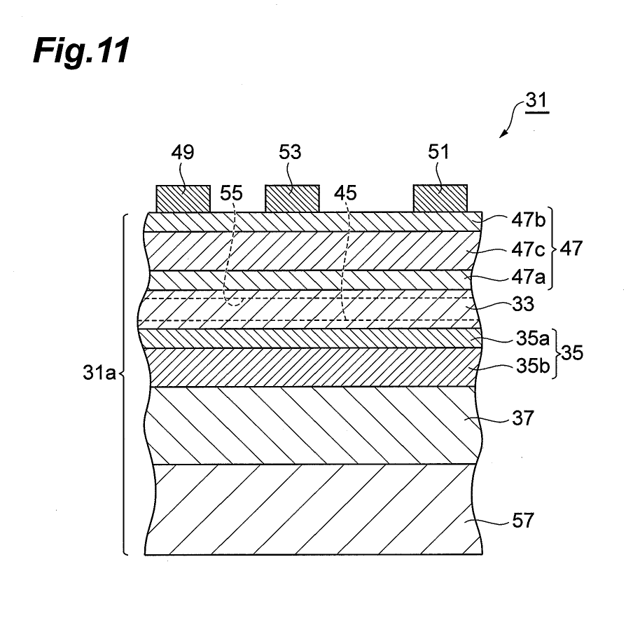

FIG. 11 is a diagram illustrating a structure of a group III nitride semiconductor device according to a fifth embodiment of the present invention. The group III nitride semiconductor device 31 of this embodiment includes a laminated semiconductor part 31a. The laminated semiconductor part 31a is one that was cut in chip form from the group III nitride laminated semiconductor wafer 11 according to the second embodiment (see FIG. 2) and includes a first Al_{X1}In_{Y1}Ga_{1-X1-Y1}N layer 33 as a channel layer, a second Al_{X2}In_{Y2}Ga_{1-X2-Y2}N layer 35 (an undoped layer 35a and a doped layer 35b) as a barrier layer, and an epitaxial layer 37. The layers 33, 35 and 37 have the same configurations as the first Al_{X1}In_{Y1}Ga_{1-X1-Y1}N layer 13, the second Al_{X2}In_{Y2}Ga_{1-X2-Y2}N layer 15, and the epitaxial layer 17, respectively, of the first embodiment and therefore detailed description of these layers will be omitted. The laminated semiconductor part 31a also includes a third Al_{X3}In_{Y3}Ga_{1-X3-Y3}N layer 47 (undoped layers 47a and 47b and a doped layer 47c). The third Al_{X3}In_{Y3}Ga_{1-X3-Y3}N layer 47 has the same configuration as the third Al_{X3}In_{Y3}Ga_{1-X3-Y3}N layer 19 (the undoped layers 19a and 19b and the doped layer 19c) of the second embodiment. The laminated semiconductor part 31a also includes an AlN substrate 57. The AlN substrate has the same configuration as the AlN substrate 27 of the first embodiment.

The group III nitride semiconductor device 31 further includes electrodes 49 and 51 provided side by side on the undoped layer 47b of the third Al_{X3}In_{Y3}Ga_{1-X3-Y3}N layer 47. The group III nitride semiconductor device 31 further includes an electrode 53 provided between the electrodes 49 and 51 on the undoped layer 47b.

If the group III nitride semiconductor device 31 is a heterojunction transistor, the electrode 49 is one of a source electrode and a drain electrode, the electrode 51 is the other of the source electrode and the drain electrode, and the electrode 53 is a gate electrode. Alternatively, if the group III nitride semiconductor device 31 is a Schottky barrier diode, the electrodes 49 and 51 are anode electrodes and the electrode 53 is a cathode electrode.

In a certain period of operation of the group III nitride semiconductor device 31, a reverse bias is applied to the electrode 53. On the other hand, in another period of operation of the group III nitride semiconductor device 31, a forward bias is applied to the electrode 53. During this operation period, the electrodes 49 and 51 provide carriers to flow through the group III nitride semiconductor device 31. Therefore, the electrodes 49 and 51 preferably form ohmic junctions with the undoped layer 47b of the third Al_{X3}In_{Y3}Ga_{1-X3-Y3}N layer 47. Furthermore, the electrode 53 preferably forms a Schottky junction with the undoped layer 47b. In the group III nitride semiconductor device 31, the heterojunction between first Al_{X1}In_{Y1}Ga_{1-X1-Y1}N layer 33 and the second Al_{X2}In_{Y2}Ga_{1-X2-Y2}N layer 35 produces a two-dimensional electron gas layer 45 inside the first Al_{X1}In_{Y1}Ga_{1-X1-Y1}N layer 33. The heterojunction between the first Al_{X1}In_{Y1}Ga_{1-X1-Y1}N 33 and the third Al_{X3}In_{Y3}Ga_{1-X3-Y3}N layer 47 produces a two-dimensional electron gas layer 55 inside the first Al_{X1}In_{Y1}Ga_{1-X1-Y1}N layer 33.

The group III nitride semiconductor device 31 of this embodiment includes a laminated semiconductor part 31a having the same configuration as the group III nitride laminated semiconductor wafer 11 of the second embodiment. Accordingly, the group III nitride semiconductor device 31 can provide a normally-off semiconductor device having high breakdown field strength and minimal crystal defects.

As described with respect to the first and second embodiments, the first Al_{X1}In_{Y1}Ga_{1-X1-Y1}N layer 33, which is a channel layer, is preferably a thin layer having a thickness of less than or equal to 50 nm, for example, in this embodiment as well. This can minimize the anisotropy of fluctuations in the crystal direction of the first Al_{X1}In_{Y1}Ga_{1-X1-Y1}N layer 33 to maintain good device characteristics, in particular, good withstand voltage and on-resistance.

The group III nitride laminated semiconductor wafer and the group III nitride semiconductor device according to the present invention are not limited to the embodiments described above but various other variations are possible. For example, while the above embodiments have been described with AlGaN as an example of the material of the channel layer (or the first semiconductor layer), the channel layer (the first semiconductor layer) of the present invention can be advantageously made of any group III nitride semiconductor that contains Al, such as InAlGaN, AlN, and InAlN. Furthermore, while the above embodiments have been described with AlN as an example of the material of the barrier layer (or the second semiconductor layer), the barrier layer (the second semiconductor layer) can be advantageously made of any group III nitride semiconductor that has a larger bandgap than the channel layer (the first semiconductor layer), such as InAlGaN, AlGaN, and InAlN.

While the principles of the present invention have been described with respect to preferred embodiments, it will be appreciated by those skilled in the art that changes can be made to the arrangements and details without departing from the principles. The present invention is not limited to the specific configurations disclosed in the embodiments. Accordingly, the rights in the scope of the patent claims, and in all modifications and changes deriving from the scope of the spirit thereof are claimed.

### INDUSTRIAL APPLICABILITY

There is provided a normally-off group III nitride semiconductor device having high breakdown field strength and minimal crystal defects and a group III nitride laminated semiconductor wafer used to make the group III nitride semiconductor device.

### REFERENCE SIGNS LIST

10-12 . . . Group III nitride laminated semiconductor wafer; 13, . . . First Al_{X1}In_{Y1}Ga_{1-X1-Y1}N layer; 15, 35 . . . Second Al_{X2}In_{Y2}Ga_{1-X2-Y2}N layer; 15a, 35a . . . Undoped layer; 15b, 35b . . . Doped layer; 17, 37 . . . Epitaxial layer; 19, 47 . . . Third Al_{X3}In_{Y3}Ga_{1-X3-Y3}N layer; 19a, 19b, 47a, 47b . . . Undoped layer; 19c, 47c . . . Doped layer; 27, 57 . . . AlN substrate; 27a, 57a . . . Main surface, 30, 31 . . . Group III nitride semiconductor device; 30a, 31a . . . Laminated semiconductor part, 39, 41, 43 . . . Electrode; 45, 55 . . . Two-dimensional electron gas layer

1. A group III nitride laminated semiconductor wafer comprising:
a substrate which is made of AlN and has a main surface along a c-axis of the AlN crystal;
a first semiconductor layer which is made of a group III nitride-based semiconductor containing Al and is provided on the main surface; and
a second semiconductor layer which is provided on the main surface, is made of a group III nitride-based semiconductor having a larger bandgap than the first semiconductor layer, and forms a heterojunction with the first semiconductor layer.

2. The group III nitride laminated semiconductor wafer according to claim 1, wherein an X-ray rocking curve half width of the group III nitride-based semiconductor containing Al in the first semiconductor layer in the c-axis direction is not more than 1.2 times an X-ray rocking curve half width of the group III nitride-based semiconductor in a direction perpendicular to the C-axis.

3. The group III nitride laminated semiconductor wafer according to claim 1, wherein the main surface is an m-plane or an a-plane of the crystal of AlN.

4. The group III nitride laminated semiconductor wafer according to claim 1, wherein the first semiconductor layer has a thickness of less than or equal to 50 nm.

5. The group III nitride laminated semiconductor wafer according to claim 1, wherein the first semiconductor layer is made of AlGaN.

6. The group III nitride laminated semiconductor wafer according to claim 1, wherein the second semiconductor layer is made of AlN.

7. The group III nitride laminated semiconductor wafer according to claim 1, further comprising a third semiconductor layer which is provided in a position on the main surface so as to sandwich the first semiconductor layer between the third semiconductor layer and the second semiconductor layer, is made of a group III nitride-based semiconductor having a larger bandgap than the first semiconductor layer, and forms a heterojunction with the first semiconductor layer.

8. The group III nitride laminated semiconductor wafer according to claim 7, wherein the third semiconductor layer is made of AlN.

9. A group III nitride semiconductor device comprising:
a substrate which is made of AlN and has a main surface along a c-axis of the AlN crystal;
a channel layer which is made of a group III nitride-based semiconductor containing Al and is provided on the main surface; and
a first barrier layer which is provided on the main surface, is made of a group III nitride-based semiconductor having a larger bandgap than the first semiconductor layer, and forms a heterojunction with the channel layer.

10. The group III nitride semiconductor device according to claim 9, wherein an X-ray rocking curve half width of the group III nitride-based semiconductor containing Al in the channel layer in the c-axis direction is not more than 1.2 times an X-ray rocking curve half width of the group III nitride-based semiconductor in a direction perpendicular to the C-axis.

11. The group III nitride semiconductor device according to claim 9, wherein the main surface is an m-plane or an a-plane of the AlN crystal.

12. The group III nitride semiconductor device according to claim 9, wherein the channel layer has a thickness of less than or equal to 50 nm.

13. The group III nitride semiconductor device according to claim 9, wherein the channel layer is made of AlGaN.

14. The group III nitride semiconductor device according to claim 9, wherein the first barrier layer is made of AlN.

15. The group III nitride semiconductor device according to claim 9, further comprising a second barrier layer which is provided in a position on the main surface so as to sandwich the channel layer between the second barrier layer and the first barrier layer, is made of a group III nitride-based semiconductor having a larger bandgap than the channel layer, and forms a heterojunction with the channel layer.

16. The group III nitride semiconductor device according to claim 15, wherein the second barrier layer is made of AlN.
